(19) United States
(12) Patent Application Publication
(10) Pub. No.: US 2016/0351508 A1
(43) Pub. Date: Dec. 1, 2016

(54) Creating Unique Device Identification For Semiconductor Devices

(71) Applicant: Texas Instruments Incorporated, Dallas, TX (US)

(72) Inventors: Venkataramanan Kalyanaraman, Dallas, TX (US); Kalyan C. Cherukuri, Allen, TX (US); Kenneth M. Butler, Richardson, TX (US)

(73) Assignee: Texas Instruments Incorporated, Dallas, TX (US)

(21) Appl. No.: 14/971,485

(22) Filed: Dec. 16, 2015

Related U.S. Application Data
(60) Provisional application No. 62/166,761, filed on May 27, 2015.

(51) Int. Cl. H01L 23/544; G06K 7/10

(52) U.S. Cl. CPC H01L 23/544; G06K 7/10722

(57) ABSTRACT

Systems and methods for creating unique device identification for semiconductor devices are described. In some embodiments, a method may include receiving a wafer identification mark printed on a semiconductor wafer having a plurality of dies fabricated thereon; receiving a leadframe identification mark printed on a leadframe configured to receive the plurality of dies during a die attach operation; and for each of the plurality of dies: (a) recording a wafer location of a given die prior to the die attach operation; (b) recording a leadframe location of the given die after the die attach operation; (c) creating a device identification mark for the given die based upon the wafer identification mark, the leadframe identification mark, the wafer location, and the leadframe location; and (d) printing the device identification mark on a package of the given die.

This application claims priority to U.S. Provisional Patent Application Ser. No. 62/166,761 titled “TECHNIQUE AND PROCEDURE FOR CREATING UNIQUE DEVICE IDENTIFICATION FOR SEMICONDUCTOR DEVICES” and filed on May 27, 2015, which is incorporated by reference herein.

### TECHNICAL FIELD

This specification is directed, in general, to electronic circuits, and, more specifically, to systems and methods for creating unique device identification for semiconductor devices.

### BACKGROUND

In chip manufacturing, multiple dies are fabricated on a single semiconductor wafer. These dies are then separated and packaged into individual chips, each having a number of integrated circuits (ICs). In order to keep track of each die during the manufacture process and beyond, each such die may be assigned a unique identifier (die ID) while on its wafer, and each wafer may be assigned to a lot. Certain additional data corresponding to the dies (e.g., product, grade, etc.) may be combined with their respective die IDs provide additional die information.

Die information is useful for tracing each individual die's history of operation(s), carrier used for its transportation, the lot it belonged to at various times, etc. For example, if a die later proves unreliable, it would be beneficial to identify the source of the die and to determine how and when the die unit was manufactured, in order to aid the semiconductor manufacturer in improving its manufacturing processes.

The inventors have recognized that the spatial position (e.g., X and Y) of a die in a wafer is a crucial piece of information in process traceability for root cause analysis of characterization issues, production yield loss, qualification failures, and customer returns. A conventional technique for obtaining and storing location information is to write that information during a probe test operation, for example, into a non-volatile memory (NVM) element of the die itself. This information can be electrically accessed after device is packaged, and it is commonly referred as “electrical die ID”.

As the inventors have also recognized, however, this conventional technique presents a number of drawbacks. First, a specific silicon area needs to be allocated in the die for identification, in cases when traceability is needed after manufacturing. Added die area increases cost of goods sold (COGS) for the product. Design and test engineering investment is needed to implement the technique in each device, which increases the cost of new product development. Second, probe testing is required. Third, because information is stored electrically, it is only possible to extract it when communication with the device's NVM is successful. Failure mechanisms such as die-crack, physical damage, wire bond failures, broken leads, electrical overstress, defects in power supply or reference blocks that prevent power-up of a device, etc. can make it impossible to read traceability information from the NVM. Due to these, and other limitations, electrical die ID methods are only used in a small fraction of devices.

### SUMMARY

Systems and methods for creating unique device identification for semiconductor devices are described. In an illustrative, non-limiting embodiment, a method may comprise: receiving a wafer identification mark printed on a semiconductor wafer having a plurality of dies fabricated thereon; receiving a leadframe identification mark printed on a leadframe configured to receive the plurality of dies during a die attach operation; and for each of the plurality of dies: (a) recording a wafer location of a given die prior to the die attach operation; (b) recording a leadframe location of the given die after the die attach operation; (c) creating a device identification mark for the given die based upon the wafer identification mark, the leadframe identification mark, the wafer location, and the leadframe location; and (d) printing the device identification mark on a package of the given die.

For example, the wafer identification mark and/or the leadframe identification mark may include a laser scribed mark, an etched mark, an inked mark, or a bar code. The wafer location may include a Cartesian coordinate of the given die relative to a reference point on the semiconductor wafer. The leadframe location may include a Cartesian coordinate of the given die relative to a reference point on the leadframe.

Creating the device identification mark may include performing an encryption or hash operation upon a combination of the wafer identification mark, the leadframe identification mark, the wafer location, and the leadframe location. Printing the device identification mark may include laser scribing, etching, or inking the mark on a surface of the package.

The method may include storing, in a database, for each of the plurality of dies, an association among the wafer identification mark, the leadframe identification mark, the wafer location, the leadframe location, and the device identification mark. The method may also include: receiving a device identification mark printed on an electronic device; and accessing the database to retrieve the wafer identification mark, the leadframe identification mark, the wafer location, and the leadframe location associated with the device identification mark.

In some cases, the receiving and accessing may be performed as part of a counterfeit detection operation. Additionally or alternatively, the receiving and accessing may be performed as part of a temperature coefficient testing operation.

In another illustrative, non-limiting embodiment, an electronic device may include a die and a package surrounding at least a portion of the die, wherein the package includes a visual device identification mark that uniquely associates the die with a wafer identification mark, a leadframe identification mark, a wafer location, and a leadframe location.

The visual device identification mark may include a laser scribed mark, an etched mark, an inked mark, or a bar code. The wafer location may include a coordinate of the die on a wafer and the leadframe location includes a coordinate of the die on a leadframe. The device identification mark may be created by encrypting or hashing any combination of: the wafer identification mark, the leadframe identification mark, the wafer location, or the leadframe location.

In yet another illustrative, non-limiting embodiment, a memory device may have program instructions stored thereon that, upon execution by a processor of a computer system, cause the computer system to: receive a device identification mark visually printed on a package of an electronic device comprising a semiconductor die; and retrieve, from a database, a wafer identification mark, a leadframe identification mark, a wafer location, and a leadframe location associated with the semiconductor die based upon the device identification mark.

The receiving and retrieving may be performed as part of a counterfeit detection or temperature coefficient testing operation. The device identification mark may include a laser scribed mark, an etched mark, an inked mark, or a bar code. The wafer location may include a coordinate of the semiconductor die on a wafer, and wherein the leadframe location includes a coordinate of the semiconductor die on a leadframe. The device identification mark may be created by encrypting or hashing any combination of: the wafer identification mark, the leadframe identification mark, the wafer location, or the leadframe location.

### BRIEF DESCRIPTION OF THE DRAWINGS

Reference will now be made to the accompanying drawings, wherein:

FIG. 1 is a block diagram of an example of a traceability system according to some embodiments.

FIG. 2 is a block diagram of an example of manufacturing tools usable in a traceability system according to some embodiments.

FIG. 3 is a flowchart of an example of a method for creating unique device identification for semiconductor devices according to some embodiments.

FIG. 4 is a block diagram of an example of a wafer usable in a traceability system according to some embodiments.

FIG. 5 is a block diagram of an example of a leadframe usable in a traceability system according to some embodiments.

FIG. 6 is a block diagram of an example of an electronic device packaging usable in a traceability system according to some embodiments.

FIG. 7 is a flowchart of an example of a method for using unique device identification for semiconductor devices according to some embodiments.

### DETAILED DESCRIPTION

Embodiments now will be described more fully hereinafter with reference to the accompanying drawings. The systems and methods described herein may, however, be embodied in many different forms and should not be construed as limited to the implementations set forth herein. Rather, these embodiments are provided so that this disclosure will be thorough and complete. A person of ordinary skill in the art will be able to make and use the various embodiments described herein.

The systems and methods described herein provide new procedures for storing or printing traceability information on the package of an electronic device; procedures which may be enabled in existing assembly processes. In many implementations, information is not stored in the die itself, thus resulting in a significantly cheaper solution (compared to electrical die IDs). No die design changes are needed, and these techniques may be applied to existing devices in production. Also, no probe testing is required. No design or test engineering investment is needed for new products or production devices. Moreover, because traceability information may be visually or optically printed on a device's package, electrical failure of the die does not impede traceability.

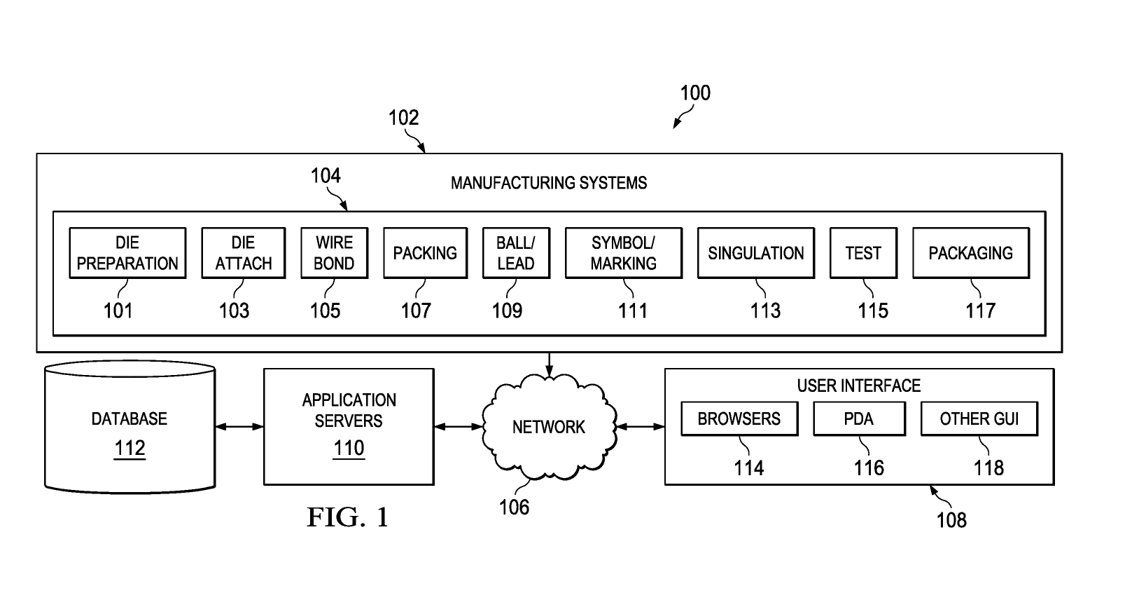

FIG. 1 is a block diagram of an example of a traceability system, which in this case is configured to facilitate the tracing of dies, by way of example and not limitation, during a transfer from one factory or lot to another. Traceability system 100 can include one or more manufacturing systems 102, testing, assembly and packaging system 104, host network 106, user interface 108, application server 110, and database 112. Testing, assembly and packaging system 104 can include devices for performing numerous semiconductor fabrication operations including, for example, die preparation 101, die attach 103, wirebonding 105, molding 107, ball lead 109, symbol/marking 111, singulation 113, testing 115, and packaging 117.

Generally speaking, die preparation operation 101 receives a wafer and performs one or more chemical or physical processing steps, including, for example, sawing each individual die away from the wafer. In some cases, the wafer may include a wafer ID that is visually or optically printed thereon. During die attach operation 103, individual dies are attached to leadrames. Each leadframe may also include a leadframe ID printed thereon.

Wire bonding 105 is a method of making interconnections with a die or between different dies. Molding 107 is an electronic packaging process where a die is encapsulated with Epoxy Molding Compound (EMC) to prevent physical damage or corrosion, for example, such that the encapsulant material becomes the device's package. Ball/lead operation 109 adds solder balls or leads to the terminals of a resulting electronic device's package. Symbolization operation 111 prints or engraves logos, names, symbols or other information on the surface of the device's electronic package. Singulation operation 113 divides the resulting devices into discrete elements. Test operation 115 includes electrical and functional testing of the device. And packing operation 117 refers to the packing (but not to be confused with the electronic packaging of operation 107) of the resulting devices in boxes prior to shipping to customers.

As a person of ordinary skill in the art will recognize in light of this disclosure, any number of different semiconductor manufacturing processes and operations may be contemplated for use with system 100.

In various embodiments, application server 110 generates unique device IDs for each die. Application server 110 assigns the device IDs in one-to-one correspondence to the dies. Additionally or alternatively, device IDs may be generated by the manufacturing system 102. These device IDs are then stored in the database 112.

As to the tracing of individual dies and their histories as they proceed through manufacturing system 102, embodiments described herein associate, for each device ID corresponding to each given die: a wafer ID, a leadframe ID, a location of the given die on the wafer (wafer location) prior to die attach operation 103, and a location of the given die on the leadframe (leadframe location) after die attach operation 103.

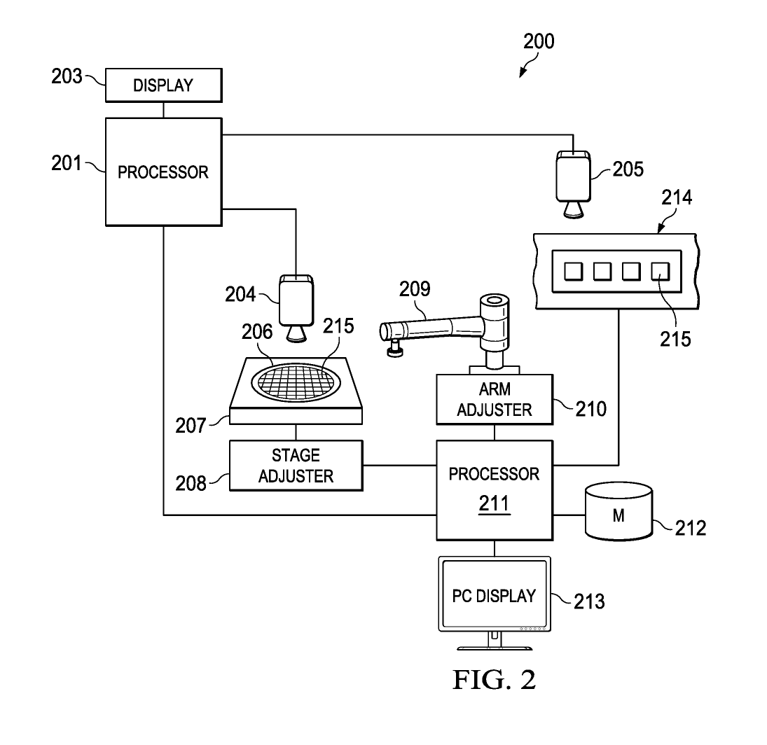

For example, wafer location information may be obtained, for each die, from a suitable device used during die preparation operation 101. Moreover, a die bonder tool used during die attach operation 103 may provide leadframe location information for each die. Wafer ID and leadframe ID may be obtained from any camera or optical sensor used in testing, assembly and packaging system 104, as shown in FIG. 2. These various pieces of information may be stored in database 212 and correlated to one another via the device ID, which may then be printed on the package of the electronic device.

Manufacturing system 102 may transmit data related to the transfer operation of die units performed by each device in testing, assembly and packaging system 104 to application server 110. Application server 110 receives this data via the network 106 and stores the resulting information (e.g., string(s)) in the database 112. In this fashion, system 100 traces a particular die's history as it is passed from one point to another. User interface 108 enables a user operating browsers 114, tablets/cellphones/personal digital assistants 116, or other graphical user interface devices 118 to interact with application sever 110, for example, to retrieve information from database 112.

Referring to FIG. 2, a block diagram of an example of manufacturing tools 200 usable in traceability system 100 are described. In various embodiments, tools 200 may be used to perform one or more operations involved, for example, in die attach process 103. As shown, silicon wafer 206 is carried by table 207 which is moveable in conjunction with a table or stage adjuster 208. Robot 209 includes a controllable arm adjuster 210 that allows it to picks up individual dies 215 from wafer 206 and to places those dies 215 on leadframe 214.

Wafer table 207 via adjuster 208 moves wafer 206 to locate the next die under program control of processor 211 so that robot arm 209 picks up die 215 from wafer 206 and places it on leadframe 214. After table 207 is moved to a known good die, an output signal is produced by processor 211 and, the output signal may be delivered to the adjuster 208 so as to reposition wafer table 207. In some cases, the location of the die on the wafer is recorded. These operations may be displayed by processor 201 on display 203 or by processor 211 on display 213.

Arm adjuster 210 and stage adjuster 208 are controlled by processor 211. A leadframe handling system may move and position leadframe 214 to allow proper placement of the dies 215. For example, such a leadframe handling system may apply epoxy to pads of leadframe 104 before dies 215 are placed on leadframe 214. In some cases, the location of the die on leadframe 214 is also recorded.

In order to perform a visual reading of markings imprinted upon wafer 206 and leadframe 214, processor 211 receives video or still images from video cameras 204 and 205 (such as a CCD camera), respectively. In some implementations, cameras 204 and 205 may include optic components that enable it focus on those visual or optical markings.

In sum processor 211 may therefore receive information regarding a wafer ID, leadframe ID, wafer location, and leadframe location for each individual die during various semiconductor manufacturing operations. These, and other useful pieces of information, may be stored in memory or database 212.

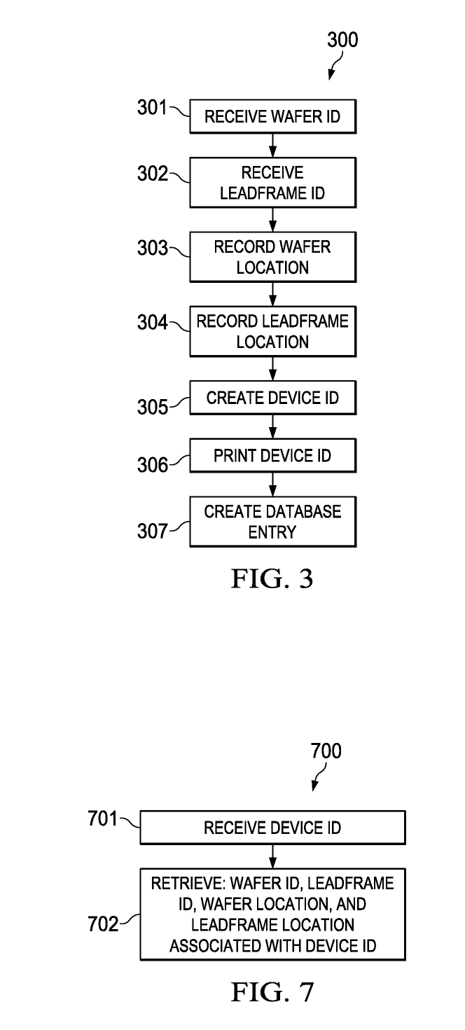

FIG. 3 is a flowchart of an example of method 300 for creating unique device identification for semiconductor devices. In various embodiments, the operations of method 300 may be used together or in subsets to achieve unique device level identification in an assembly process with no design change to the underlying dies.

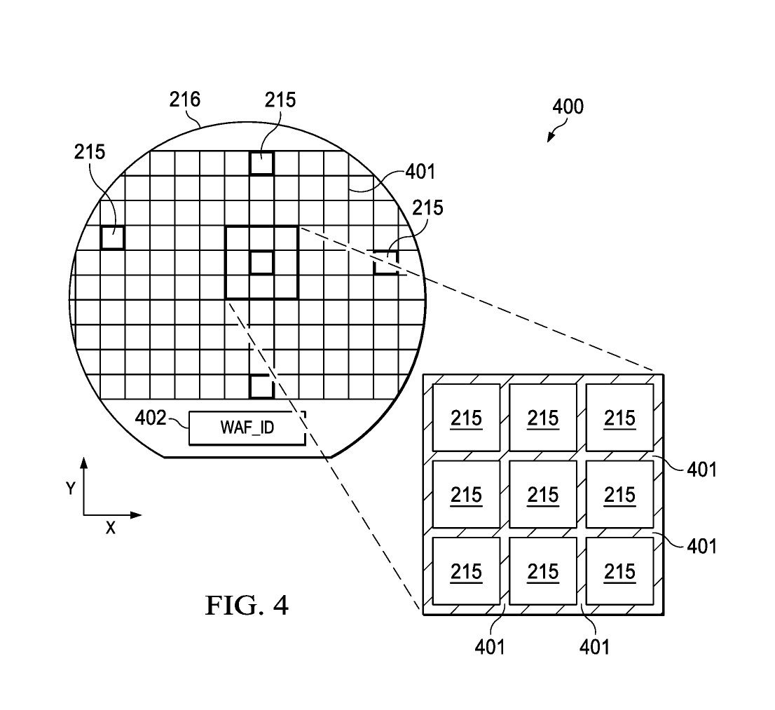

At block 301, method 300 may receive a wafer ID, for example, via camera 205. When a wafer is loaded on to die-attach tool, the wafer ID that is scribed onto the bottom of the wafer (or some other unique identifier) for the wafer is loaded into the tool. An example of wafer 206 is illustrated in system 400 of FIG. 4. Particularly, wafer 216 includes a plurality of dies 215 spaced by horizontal and vertical gaps 401. The unique identifier for wafer 216 is recorded as WAF_ID 402; which may also enable the die-attach tool to pull a wafer map for wafer 216 as part of a pick operation.

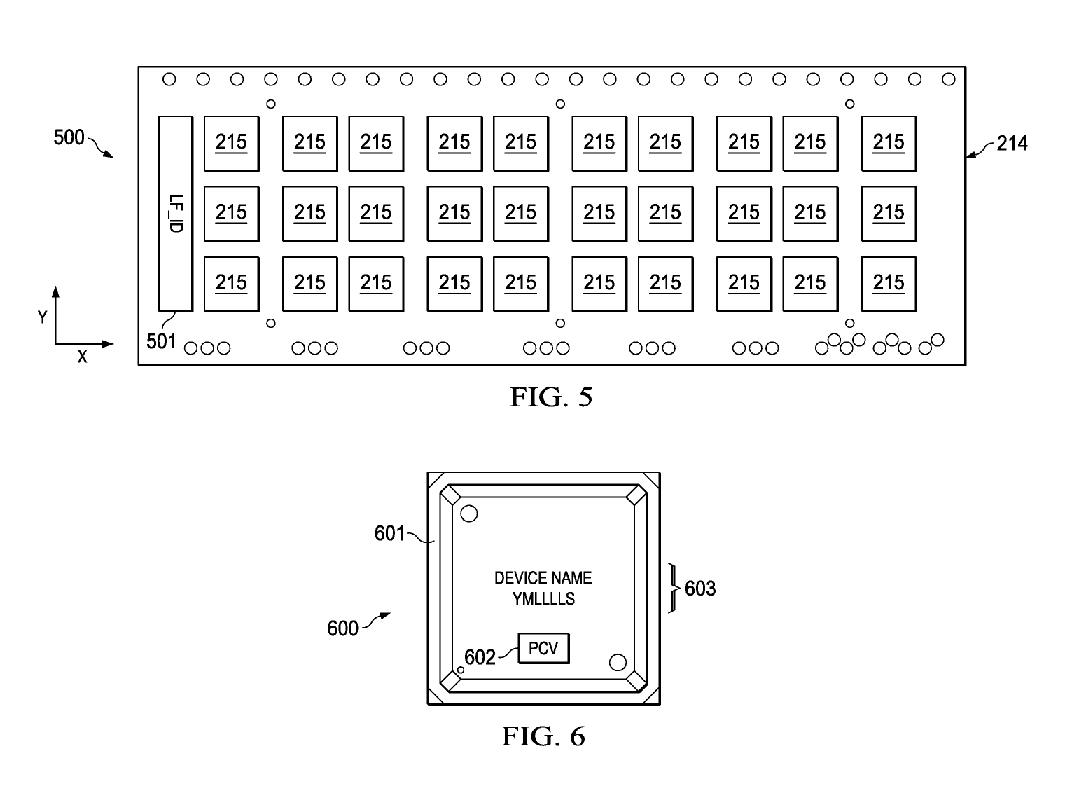

At block 302, method 300 may receive a leadframe ID. An example of leadframe 214 is illustrated in system 500 of FIG. 5. Specifically, leadframe 214 includes strips of pads upon which dies 215 are mounted. The unique identifier for leadframe 214 is recorded as LF_ID 501 prior to a die-attach operation in integrated circuit (IC) assembly.

In various embodiments, visual or optical marks 402 and 501 imprinted upon wafer 206 and leadframe 214 may be made with multiple techniques including, but not limited to, laser scribing, etching, physical inking, or bar code strips. This may be done in any location like clamp holder, without any change to underlying leadframe strip design. Moreover, this may be done in assembly site or it may be included in specification for vendor to implement in the leadframe manufacturing process.

LF_ID 501 may be read with camera system 205 of a die-attach tool 200 and stored digitally. The digital LF_ID number is created prior to the start of the die-attach operation. Then, a reader system such as barcode or camera may be added to die-attach tool to read LF_ID using optical character recognition or bar code decoding. Software may allow for manual entry or override of LF_ID by an assembly operator.

The die-attach tool sequentially picks each die 215 from wafer 206 and mounts it onto a leadframe pad or slot. That is, once wafer 206 is loaded and leadframe 214 is positioned for assembly, movable arm 209 picks one die 215 at a time. The Cartesian (X, Y) coordinates or locations of a given die relative to a fixed point in wafer 206 (wafer location; DIE_X, DIE_Y) is recorded at block 303. Arm 209 then moves on top of an open position in leadframe 214 and places die 215 on a strip of adhesive material. The location where that given die is placed relative to a fixed point in leadframe 214 (leadframe location; LF_X, LF_Y) is also recorded at block 304. Database 212 stores this information for each die in the assembly lot.

In some cases, other methods for identifying the location of a die in a wafer and/or leadframe, and or other coordinate systems may be used. Moreover, any optical fingerprinting method, such as, but not limited to, image of a die or scan of topographical profile may also be used in isolation or in conjunction with above the method to build a unique optical signature for each die.

At block 305, a unique device identification code (DEV_ID) is generated in database 212 for every die 215. This device ID, in combination with a lot trace code already physically inscribed on each device, may serve as a unique identifier for the unit allowing full traceability back through wafer manufacturing. In some cases, the device ID may be obtained by (a) creating any combination of wafer identification, leadframe identification, wafer location, and leadframe location, or any portion thereof, and (b) encoding the resulting information or string with a secure encryption key or hash algorithm. In some cases, the assembly lot number may also be used in this process along with other traceability data.

To illustrate the types of traceability data that may be stored in database 212, consider Table I below:

TABLE I

| Assembly Lot | WAF_ID | DIE_X | DIE_Y | LF_ID | LF_X | LF_Y | DEV_ID |
|---|---|---|---|---|---|---|---|
| 6531089 | C-5554321-01 | 43 | 45 | SM-2131122-22 | 12 | 13 | PCV |
| 6531089 | C-5554321-01 | 43 | 46 | SM-2131122-22 | 12 | 14 | MVN |
| 6531089 | C-5554321-01 | 43 | 47 | SM-2131122-22 | 12 | 15 | CPS |

Table I shows traceability data stored for three different dies, all of which have the same assembly lot, WAF_ID, and LF_ID; but each die has different wafer and leadframe locations, and therefore unique resulting DEV_IDs.

At block 306, method 300 includes optically or visually printing or marking the DEV_ID upon each respective device containing one of dies 215, for example, as part of symbol or marking operation 111 in FIG. 1. An instance of electronic device 601 is illustrated in system 600 of FIG. 6. Particularly, device 601 includes area 603 with markings such as logos, part names, etc. Moreover, device 601 also includes DEV_ID 602 imprinted upon its packaging, for example, using a laser or other suitable process. Markings may be made in alphanumeric, 2D barcode, etc. based on area available and additional encoding adding security when required.

As such, the DEV_ID marked on a chip or device package may be read at final test operation by automated test equipment and recorded with test data as traceability information for unit at block 307 in the form of an entry in database 212.

FIG. 7 is a flowchart of an example of a method for using unique device identification for semiconductor devices. In some embodiments, method 700 may be performed by a user operating user interface 108 of FIG. 1. At block 701, method 700 receives a DEV_ID, for example, based upon visual inspection of an electronic device. Then, at block 702, method 700 retrieves from database 212 information such as wafer identification, leadframe identification, wafer location, leadframe location, and/or assembly lot number for that device.

In various embodiments, the systems and methods described herein enable wafer ID and location information to be obtained during a die-attach operation. Probe testing is not necessary for this method, lowering COGS. Data may be marked on an encapsulating package using commonly available laser scribe infrastructure. There is no added die area; die size reduction can also lead to smaller packages which is a competitive advantage. No non-volatile memory element is needed in the die. Due to the lack of requirement for NVM, this technique is applicable to more semiconductor process technologies than techniques which require NVM. Moreover, traceability of dies within the assembly process is provided without electrical access to the units (traceability is also enabled for analog dies and other components that do not have digital memories by design). These methods are scalable across all wafer fabrication processes.

The techniques described herein provide a factory-level solution. No significant product level design, test engineering time, or investment is needed. A one-time infrastructure investment enables all current production and future products to leverage this approach.

As a person of ordinary skill in the art will recognize in light of this disclosure, the systems and methods described herein enable a number of new applications. For example, package marking may be photographed and emailed to begin customer return processing.

Customers that require preliminary investigation reports based on lot trace code information benefit from being able to extract internal test data and processing history of failing units from a manufacturer's system. (With electrical die ID, this process takes multiple days as customer has to physically return the failing unit to the manufacture and unit must then be tested to extract the die ID.) If communication of device is impacted by a failure, then it may not be possible to extract die ID.

Package markings may be read by post test tools such as tape and reel to enable post final test sorting of units based on wafer/unit statistics.

Wafer-level statistical screening methods may be performed offline after final test operation to identify outliers/triggers. By reading package marking, post-final test tools such as, but not limited to, tape and reel machine, may bin out outliers. Performing wafer-level outlier detection for non-probe devices is a unique competitive advantage.

High performance and sensor conditioning circuits require guarantee of temperature drift by testing. Currently, this is either performed by specialized systems that can alter temperature during testing (impact is low throughput) or by addition of a memory into the device to store temperature data. With the techniques described herein, however, unit-level test information may be retrieved across two test insertions at different temperatures and bin units based on temperature drift at tape and reel operation.

Many customers request serialized qualification—that is, unit level traceability and data analysis of pre- and post-qualification stress test data—to identify drifts. Currently for devices without electrical die IDs, this is done by manually marking parts and tracking them by hand test. This is a very low throughput and high cost operation. With the systems and methods described herein, as each manufactured unit is marked already and the test system has ability to read this marking automatically, unit-level analysis of qualification becomes easy.

Furthermore, because each device for a material is uniquely marked with encoded data and key for each device, counterfeit detection is possible at a unit level.

It should be understood that the various operations described herein may be implemented by processing circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

A person of ordinary skill in the art will appreciate that the various circuits depicted above are merely illustrative and is not intended to limit the scope of the disclosure described herein. In addition, the operations performed by the illustrated components may, in some embodiments, be performed by fewer components or distributed across additional components. Similarly, in other embodiments, the operations of some of the illustrated components may not be provided and/or other additional operations may be available. Accordingly, systems and methods described herein may be implemented or executed with other circuit configurations.

It will be understood that various operations discussed herein may be executed simultaneously and/or sequentially. It will be further understood that each operation may be performed in any order and may be performed once or repetitiously.

Many modifications and other embodiments will come to mind to a person of ordinary skill in the art to which such embodiments pertain having the benefit of the teachings presented in the foregoing descriptions, and the associated drawings. Therefore, it is to be understood that the embodiments are not to be limited to the specific implementations disclosed. Although specific terms are employed herein, they are used in a generic and descriptive sense only and not for purposes of limitation.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A method, comprising:
receiving a wafer identification mark printed on a semiconductor wafer having a plurality of dies fabricated thereon;
receiving a leadframe identification mark printed on a leadframe configured to receive the plurality of dies during a die attach operation; and
for each of the plurality of dies:
(a) recording a wafer location of a given die prior to the die attach operation;
(b) recording a leadframe location of the given die after the die attach operation;
(c) creating a device identification mark for the given die based upon the wafer identification mark, the leadframe identification mark, the wafer location, and the leadframe location; and
(d) printing the device identification mark on a package of the given die.

2. The method of claim 1, wherein the wafer identification mark includes a laser scribed mark, an etched mark, an inked mark, or a bar code.

3. The method of claim 1, wherein the leadframe identification mark includes a laser scribed mark, an etched mark, an inked mark, or a bar code.

4. The method of claim 1, wherein the wafer location includes a Cartesian coordinate of the given die relative to a reference point on the semiconductor wafer.

5. The method of claim 1, wherein the leadframe location includes a Cartesian coordinate of the given die relative to a reference point on the leadframe.

6. The method of claim 1, wherein creating the device identification mark comprises performing an encryption or hash operation upon a combination of the wafer identification mark, the leadframe identification mark, the wafer location, and the leadframe location.

7. The method of claim 1, wherein printing the device identification mark includes laser scribing, etching, or inking the mark on a surface of the package.

8. The method of claim 1, further comprising:
storing, in a database, for each of the plurality of dies, an association among the wafer identification mark, the leadframe identification mark, the wafer location, the leadframe location, and the device identification mark.

9. The method of claim 8, further comprising:
receiving a device identification mark printed on an electronic device; and
accessing the database to retrieve the wafer identification mark, the leadframe identification mark, the wafer location, and the leadframe location associated with the device identification mark.

10. The method of claim 9, wherein the receiving and accessing are performed as part of a counterfeit detection operation.

11. The method of claim 9, wherein the receiving and accessing are performed as part of a temperature coefficient testing operation.

12. An electronic device, comprising:
a die; and
a package surrounding at least a portion of the die, wherein the package includes a visual device identification mark that uniquely associates the die with a wafer identification mark, a leadframe identification mark, a wafer location, and a leadframe location.

13. The electronic device of claim 12, wherein the visual device identification mark includes a laser scribed mark, an etched mark, an inked mark, or a bar code.

14. The electronic device of claim 12, wherein the wafer location includes a coordinate of the die on a wafer and the leadframe location includes a coordinate of the die on a leadframe.

15. The electronic device of claim 12, wherein the device identification mark is created by encrypting or hashing any combination of: the wafer identification mark, the leadframe identification mark, the wafer location, or the leadframe location.

16. A memory device having program instructions stored thereon that, upon execution by a processor of a computer system, cause the computer system to:
receive a device identification mark visually printed on a package of an electronic device comprising a semiconductor die; and
retrieve, from a database, a wafer identification mark, a leadframe identification mark, a wafer location, and a leadframe location associated with the semiconductor die based upon the device identification mark.

17. The memory device of claim 16, wherein the receiving and retrieving are performed as part of a counterfeit detection or temperature coefficient testing operation.

18. The memory device of claim 16, wherein the device identification mark includes a laser scribed mark, an etched mark, an inked mark, or a bar code.

19. The memory device of claim 16, wherein the wafer location includes a coordinate of the semiconductor die on a wafer, and wherein the leadframe location includes a coordinate of the semiconductor die on a leadframe.

20. The memory device of claim 19, wherein creating the device identification mark further comprises encrypting or hashing any combination of: the wafer identification mark, the leadframe identification mark, the wafer location, or the leadframe location.
